(19) United States
(12) Patent Application Publication
(10) Pub. No.: US 2018/0166574 A1
(43) Pub. Date: Jun. 14, 2018

(54) FINFET WITH EPITAXIAL LAYER HAVING OCTAGONAL CROSS-SECTION

(71) Applicant: UNITED MICROELECTRONICS CORP., Hsin-Chu City (TW)

(72) Inventors: Kai-Lin Lee, Kinmen County (TW); Zhi-Cheng Lee, Tainan City (TW); Chih-Chun Hu, Tainan City (TW)

(21) Appl. No.: 15/373,378

(22) Filed: Dec. 8, 2016

(51) Int. Cl. H01L 29/78; H01L 29/66; H01L 29/06

(52) U.S. Cl. CPC H01L 29/7851; H01L 29/0657; H01L 29/6656; H01L 29/66795

(57) ABSTRACT

A method for fabricating semiconductor device includes the steps of: forming a gate structure on a substrate; forming a first epitaxial layer adjacent to two sides of the gate structure; forming a patterned mask on the epitaxial layer; and using the patterned mask to remove part of the first epitaxial layer for forming a second epitaxial layer.

### BACKGROUND OF THE INVENTION

### 1. Field of the Invention

The invention relates to a method for fabricating semiconductor device, and more particularly to a method of forming a patterned mask on an epitaxial layer and then reshaping the epitaxial layer by using the patterned mask to remove part of the epitaxial layer.

### 2. Description of the Prior Art

With the trend in the industry being towards scaling down the size of the metal oxide semiconductor transistors (MOS), three-dimensional or non-planar transistor technology, such as fin field effect transistor technology (FinFET) has been developed to replace planar MOS transistors. Since the three-dimensional structure of a FinFET increases the overlapping area between the gate and the fin-shaped structure of the silicon substrate, the channel region can therefore be more effectively controlled. This way, the drain-induced barrier lowering (DIBL) effect and the short channel effect are reduced. The channel region is also longer for an equivalent gate length, thus the current between the source and the drain is increased. In addition, the threshold voltage of the FinFET can be controlled by adjusting the work function of the gate.

However, numerous problems still arise from the integration of fin-shaped structure and epitaxial layer in today's FinFET fabrication and affect current leakage and overall performance of the device. Hence, how to improve the current FinFET process has become an important task in this field.

### SUMMARY OF THE INVENTION

According to a preferred embodiment of the present invention, a method for fabricating semiconductor device includes the steps of: forming a gate structure on a substrate; forming a first epitaxial layer adjacent to two sides of the gate structure; forming a patterned mask on the epitaxial layer; and using the patterned mask to remove part of the first epitaxial layer for forming a second epitaxial layer.

According to another aspect of the present invention, a semiconductor device includes: a substrate; a gate structure on the substrate; and an epitaxial layer adjacent to two sides of the gate structure. Preferably, a cross-section of the epitaxial layer includes an octagon.

According to yet another aspect of the present invention, a semiconductor device includes: a substrate; a gate structure on the substrate; and an epitaxial layer adjacent to two sides of the gate structure. Preferably, a cross-section of the epitaxial layer includes a planar top surface, two inclined sidewalls connected to the planar top surface, and two curved sidewalls connected to the two inclined sidewalls.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating semiconductor device according to a preferred embodiment of the present invention.

FIG. 6 illustrates a structural view of a semiconductor device according to an embodiment of the present invention.

### DETAILED DESCRIPTION

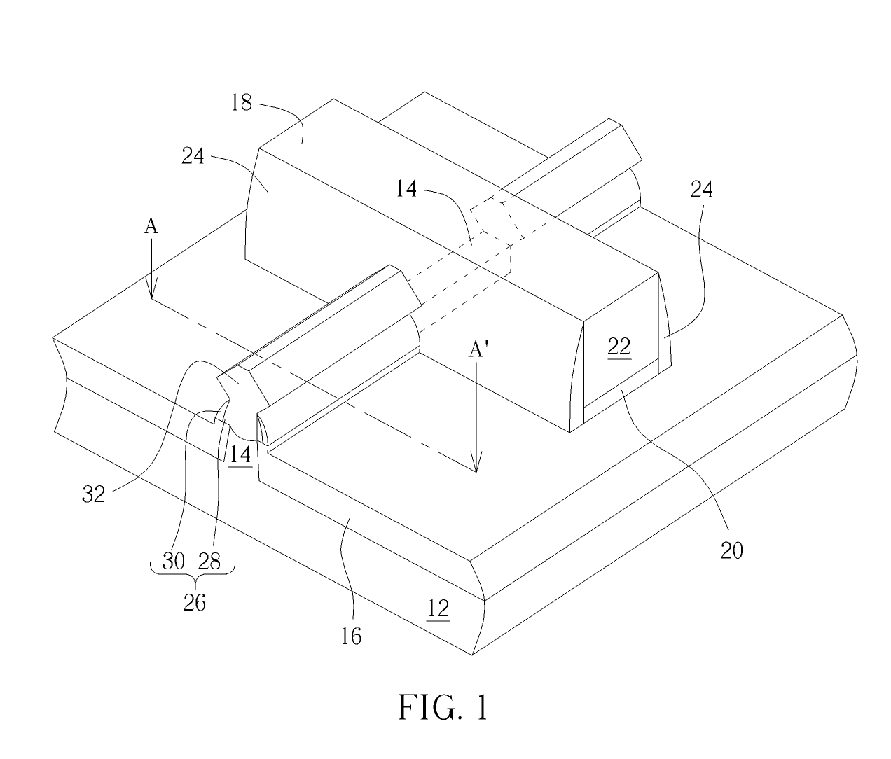

Referring to FIGS. 1-5, FIGS. 1-5 illustrate a method for fabricating semiconductor device according to a preferred embodiment of the present invention. As shown in FIG. 1, a substrate 12, such as a silicon substrate or silicon-on-insulator (SOI) substrate is provided, and a transistor region, such as NMOS region is defined on the substrate 12. At least a fin-shaped structure 14 and an insulating layer (not shown) are formed on the substrate 12, in which the bottom of the fin-shaped structure 14 is preferably enclosed by the insulating layer, such as silicon oxide to form a shallow trench isolation (STI) 16, and a dummy gate or gate structure 18 is formed on part of the fin-shaped structure 14.

In this embodiment, the fin-shaped structure 14 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structure 14 could also be obtained by first forming a patterned mask (not shown) on the substrate, 12, and through an etching process, the pattern of the patterned mask is transferred to the substrate 12 to form the fin-shaped structure 14. Moreover, the formation of the fin-shaped structure 14 could also be accomplished by first forming a patterned hard mask (not shown) on the substrate 12, and a semiconductor layer composed of silicon germanium is grown from the substrate 12 through exposed patterned hard mask via selective epitaxial growth process to form the corresponding fin-shaped structure 14. These approaches for forming fin-shaped structure are all within the scope of the present invention.

The formation of the gate structure 18 could be accomplished by a gate first process, a high-k first approach from gate last process, or a high-k last approach from gate last process. Since this embodiment pertains to a high-k last approach, a gate structure 18 composed of interfacial layer 20 and polysilicon gate 22 is formed on the fin-shaped structure 14, a spacer 24 is formed on sidewalls of the gate structure 18 and another spacer 26 is formed adjacent to the sidewalls of the fin-shaped structure 14. In this embodiment, each of the spacers 24 and 26 could be a composite spacer, in which each of the spacers 24 and 26 could further include a spacer 28 and another spacer 30. The spacers 28 and 30 could be made of same material or different material, in which the spacers 28 and 30 could be made of material including but not limited to for example SiO₂, SiN, SiON, SiCN, or combination thereof.

Next, part of the fin-shaped structure 14 is removed to form a recess (not shown) adjacent to two sides of the gate structure 18, and an epitaxial growth process is conducted to sequentially form an optional buffer layer 34 and an epitaxial layer 32 within the recess and on the fin-shaped structure 14 adjacent to two sides of the gate structure 18. Depending on the type of device being fabricated, the buffer layer 34 and the epitaxial layer 32 could be made of material including but not limited to for example SiGe, SiC, or SiP.

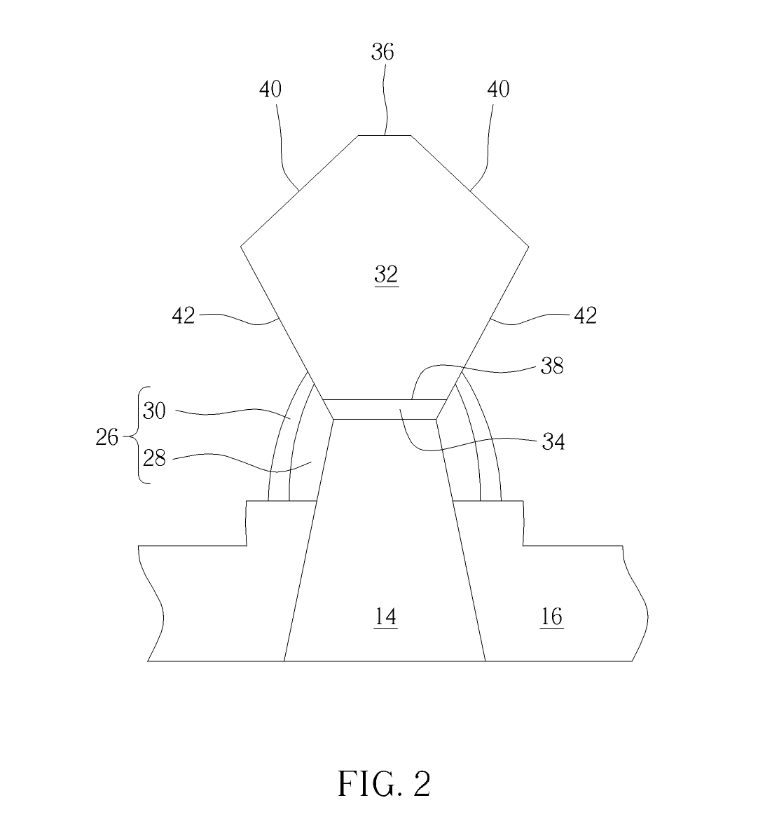

Referring to FIG. 2, FIG. 2 illustrates a cross-section view of FIG. 1 along the sectional line AA′. It is to be noted that at this stage, a cross-section of the epitaxial layer 32 along the sectional line AA′ preferably includes a hexagon or hexagonal-like shape, in which the hexagon includes a top surface 36, a bottom surface 38, two inclined sidewalls 40 connected to the top surface 36, and two inclined sidewalls 42 connected to the bottom surface 38.

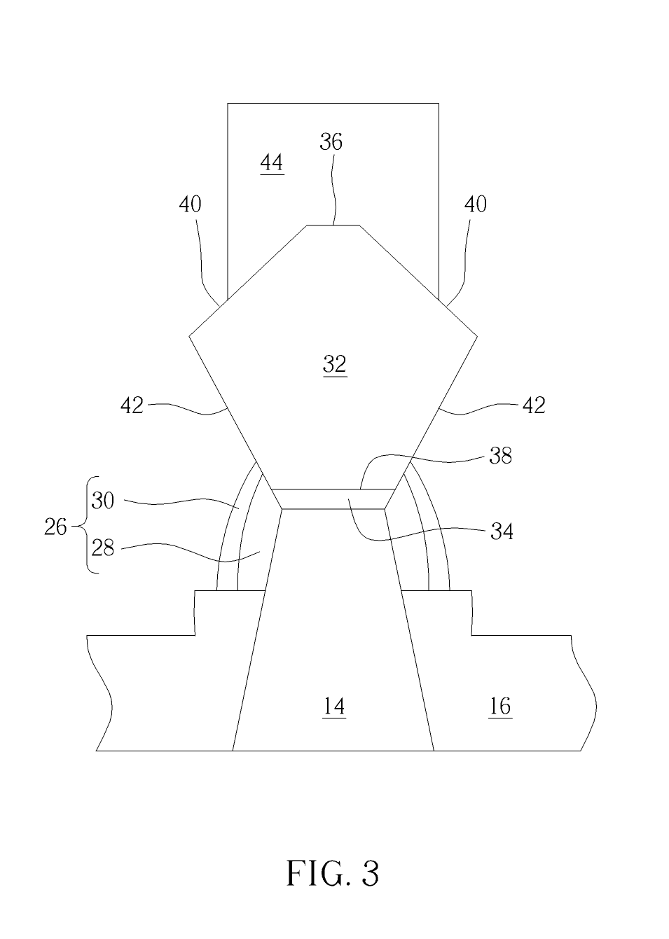

Next, as shown in FIG. 3, a patterned mask 44 is formed on the epitaxial layer 32, in which the patterned mask 44 is disposed to cover only the top surface 36 and part of the two inclined sidewalls 40 of the hexagon. In this embodiment, the patterned mask 44 is preferably a patterned resist, but not limited thereto.

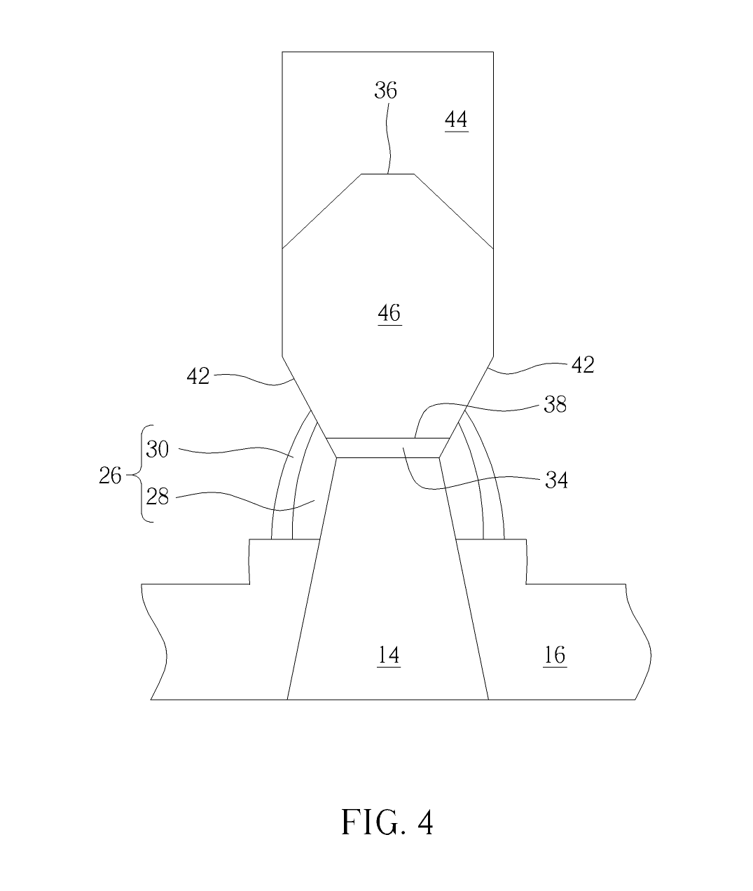

Next, as shown in FIG. 4, an etching process is conducted by using the patterned mask 44 as mask to remove part of the epitaxial layer 32 not covered by the patterned mask 44, particularly the intersecting portion between the inclined sidewalls 40 and inclined sidewalls 42. This reshapes the original hexagonal epitaxial layer 32 into a new epitaxial layer 46.

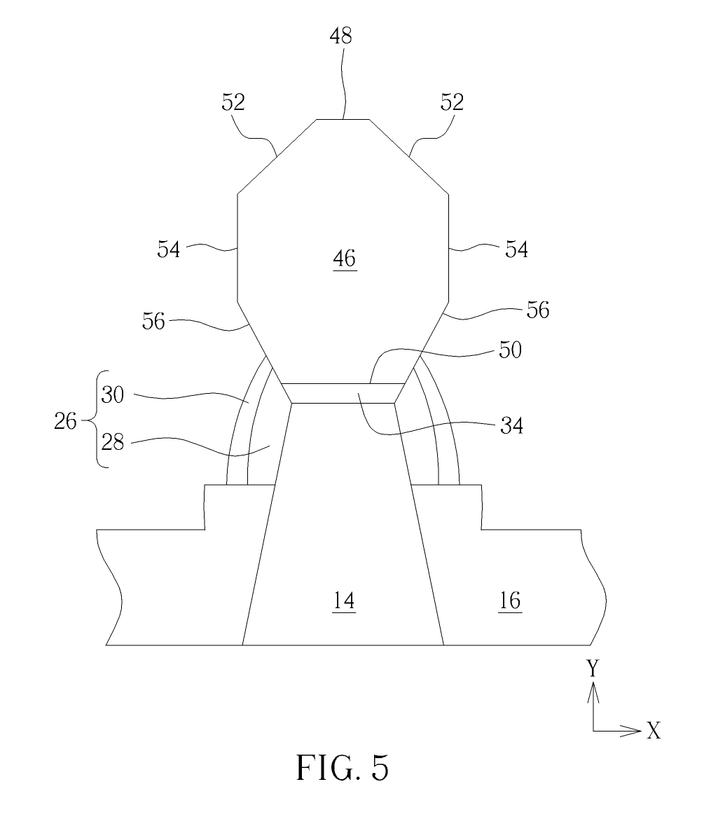

After removing the patterned mask 44, as shown in FIG. 5, a reshaped epitaxial layer 46 is formed, in which the newly formed epitaxial layer 46 preferably has a cross-section of an octagon. Viewing from a more detailed perspective, the octagon preferably includes a top surface 48, a bottom surface 50, two inclined sidewalls 52 connected to the top surface 48, two planar sidewalls 54 connected to the two inclined sidewalls 52, and two more inclined sidewalls 56 connected to the planar sidewalls 54 and the bottom surface 50 of the epitaxial layer 46.

In this embodiment, both the top surface 48 and bottom surface 50 of the octagon are planar surfaces extending along an x-axis while the both surfaces 48, 50 could also be in parallel with the top surface of the fin-shaped structure 14 and/or STI 16.

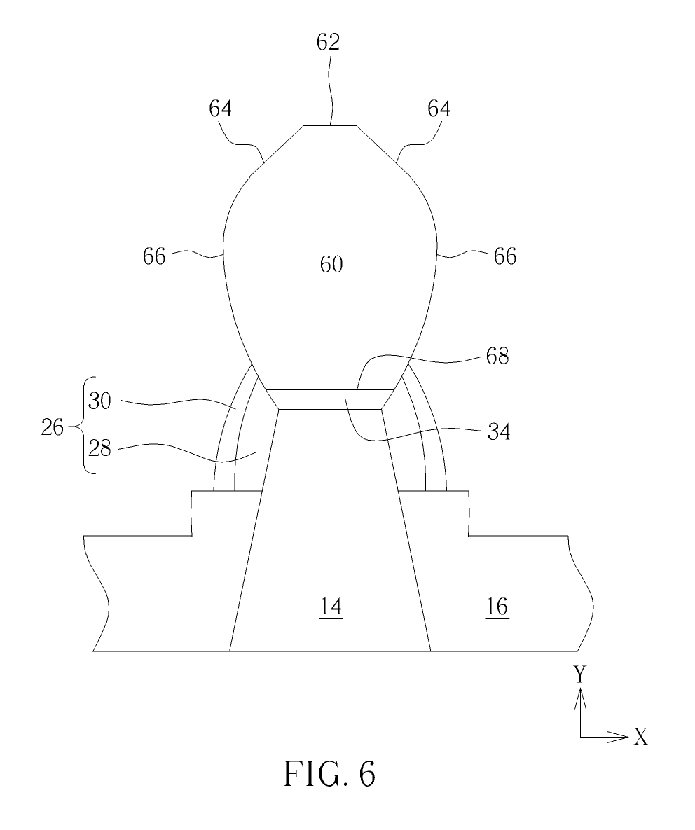

Referring to FIG. 6, FIG. 6 illustrates a structural view of a semiconductor device according to an embodiment of the present invention. As shown in FIG. 6, after stripping the patterned mask 44 as shown in FIG. 5, it would be desirable to conduct additional trimming or cleaning processes to smoothen or eliminate the angular edges of the epitaxial layer, in particular the angles between two inclined sidewalls 52 and the two planar sidewalls 54 and also the angles between two planar sidewalls 54 and the two inclined sidewalls 56.

This reshapes the octagonal epitaxial layer 46 into a structure having angular edges on the top portion and slightly elliptical sidewalls on the bottom portion. Specifically, the reshaped epitaxial layer 60 adjacent to two sides of the gate structure 18 now includes a planar top surface 62, two inclined sidewalls 64 connected to the planar top surface 62, two curved sidewalls 66 connected to the two inclined sidewalls 64, and a planar bottom surface 68 connected to the two curved sidewalls 66. Preferably, both the planar top surface 62 and planar bottom surface 68 of the newly shaped epitaxial layer 60 are formed extending along an x-axis while the both surfaces 62, 68 could also be in parallel with the top surface of the fin-shaped structure 14 and/or STI 16. The fin-shaped structure 14 is disposed directly under the planar bottom surface 68 and spacers 28, 30 are formed adjacent to the fin-shaped structure 14. This completes the fabrication of a semiconductor device according to a preferred embodiment of the present invention.

After the epitaxial layer 32 is reshaped into an epitaxial layer 46 having octagonal cross-section as shown in FIG. 5 or an uneven or irregular shaped epitaxial layer 60 shown in FIG. 6, typical FinFET fabrication process could be carried out by forming an interlayer dielectric (ILD) layer on the substrate 12 to cover the gate structure 18 and epitaxial layer, and then conducting a replacement metal gate (RMG) process to transform the gate structure 18 into metal gate. Since the RMG process is well known to those skilled in the art, the details of which are not explained herein for the sake of brevity.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
forming a gate structure on a substrate;
forming a first epitaxial layer adjacent to two sides of the gate structure;
forming a patterned mask on the epitaxial layer; and
using the patterned mask to remove part of the first epitaxial layer for forming a second epitaxial layer.

2. The method of claim 1, further comprising:
forming a fin-shaped structure on the substrate;
forming the gate structure astride the fin-shaped structure;
forming a spacer adjacent to the gate structure and the fin-shaped structure;
forming the first epitaxial layer adjacent to the spacer.

3. The method of claim 1, wherein a cross-section of the first epitaxial layer comprises a hexagon.

4. The method of claim 1, wherein a cross-section of the second epitaxial layer comprises an octagon.

5. The method of claim 4, wherein a top surface of the second epitaxial layer comprises a planar surface.

6. The method of claim 5, further comprising two inclined sidewalls connected to the planar surface.

7. The method of claim 6, further comprising two planar sidewalls connected to the two inclined sidewalls.

8. The method of claim 1, wherein a top surface of the second epitaxial layer comprises a planar surface.

9. The method of claim 8, further comprising two inclined sidewalls connected to the planar surface.

10. The method of claim 9, further comprising two curved sidewalls connected to the two inclined sidewalls.

11. A semiconductor device, comprising:
a fin-shaped structure on a substrate;
a gate structure on the fin-shaped structure and the substrate; and
an epitaxial layer adjacent to two sides of the gate structure, wherein a cross-section of the epitaxial layer comprises an octagon and a width of a top surface of the octagon is less than a width of a top surface of the fin-shaped structure and the width of the top surface of the fin-shaped structure is less than a width of a bottom surface of the octagon.

12. The semiconductor device of claim 11, wherein a top surface of the epitaxial layer comprises a planar surface.

13. The semiconductor device of claim 12, further comprising two first inclined sidewalls connected to the planar surface.

14. The semiconductor device of claim 13, further comprising two planar sidewalls connected to the two first inclined sidewalls.

15. The semiconductor device of claim 14, further comprising two second inclined sidewalls connected to the two planar sidewalls and a bottom surface of the epitaxial layer.

16. The semiconductor device of claim 15, further comprising a fin-shaped structure under the bottom surface.

17. A semiconductor device, comprising:
a substrate;
a gate structure on the substrate; and
an epitaxial layer adjacent to two sides of the gate structure, wherein a cross-section of the epitaxial layer comprises a planar top surface, two inclined sidewalls connected to the planar top surface, and two curved sidewalls connected to the two inclined sidewalls.

18. The semiconductor device of claim 17, further comprising a planar bottom surface connected to the two curved sidewalls.

19. The semiconductor device of claim 18, further comprising a fin-shaped structure under the planar bottom surface.

20. The semiconductor device of claim 19, further comprising a spacer adjacent to the fin-shaped structure.
